(19) United States
(12) Patent Application Publication
(10) Pub. No.: US 2025/0042726 A1
(43) Pub. Date: Feb. 6, 2025

(54) A METHOD OF FABRICATING NANOPORES

(71) Applicant: AUSTRALIAN NATIONAL UNIVERSITY, Australian Capital Territory (AU)

(72) Inventors: Shankar DUTT, Australian Capital Territory (AU); Christian NOTTHOFF, Australian Capital Territory (AU); Patrick KLUTH, Australian Capital Territory (AU)

(73) Assignee: AUSTRALIAN NATIONAL UNIVERSITY, Australian Capital Territory (AU)

(21) Appl. No.: 18/717,398

(22) PCT Filed: Dec. 7, 2022
(86) PCT No.: PCT/AU2022/051467

§ 371 Date: Jun. 6, 2024

(30) Foreign Application Priority Data
Dec. 7, 2021 (AU) 2021903959

(51) Int. Cl. B81C 1/00; B01D 61/02; B01D 67/00; B01D 69/02; B01D 69/12; B01D 71/02; B81B 1/00

(52) U.S. Cl. CPC B81C 1/00539; B01D 61/027; B01D 67/0062; B01D 69/02; B01D 69/1216; B01D 71/0213; B01D 71/0215; B01D 71/027; B81B 1/004; B01D 2323/34; B01D 2325/0214; B01D 2325/04

(57) ABSTRACT

A method of fabricating nanopores in a-material, the method comprising: irradiating the material to create a track of damage in the material, the track of damage having one or more dimensions in the nanometre range; and etching the track of damage with an etchant to produce a nanopore.

### TECHNICAL FIELD

This disclosure relates to a method of fabricating nanopores in a material and a membrane having one or more nanopores fabricated using such method. The disclosure also relates to a membrane having one or more nanopores therein.

### BACKGROUND

A nanopore is a pore or a cavity having dimension/s in the nanometer range. Nanopores may comprise narrow channels in a material, such as in a membrane, with one or more dimensions in the nanometer range. Nanopores can be found in biological systems such as in cell membranes, lipid bilayers, etc. Nanopores can also be fabricated artificially for many applications.

A membrane is a barrier that selectively allows some things, such as molecules or ions, to pass through but stops others based on the properties of the membrane material and/or introduction of functional elements such as nanopores. Nanopore membranes are membranes having one or more nanopores therein. They are currently used in many applications, including the areas of filtration, bio- and chemical-sensing, size-selective transport of ions, water desalination, ion pumps, molecular sieving, protein detection, gas sensing, nano-fluidics, DNA sequencing and bioelectronicsnd. Nanopore membranes are also used for ion current rectification (ICR) in that the nanopores essentially behave like electronic diodes when immersed in an electrolyte by transporting ions more efficiently in one direction than in the other depending on the cross membrane bias polarity. The industrial use of nanopore membranes is also steadily increasing. While the present specification will focus on the manufacture of silicon based nanopore membranes, it is to be understood that the invention is not limited to membranes having such a composition.

Various artificial nanopore membranes have been fabricated using different materials and methods. However, silicon-based nanopore membranes (such as silicon dioxide, silicon nitride and silicon oxynitride based membranes) have more recently attracted the scientific attention of researchers due to their superior mechanical, thermal, and chemical stability, robustness, adjustable surface properties, nanopore functionalization, and compatibility and easy integration in solid-state devices.

Nanopores in silicon-based membranes are currently fabricated using two main methods, namely, controlled dielectric breakdown, and ion/electron beam sculpting. However, the ion/electron beam sculpting and the controlled dielectric breakdown techniques are not scalable, and the repeatability of the experiments is not acceptable.

Further, there has been some research on the use of hydrofluoric acid (HF) to form pores in some inorganic thin films. However, the use of HF is very problematic given that it is a highly toxic and corrosive acid and therefore presents significant safety risks. Additionally, using HF as an etchant, does not provide control over the shape and size of the pores (ie, the “tunability” of the pores).

There is accordingly a need for a method of fabricating nanopores in a membrane material that has acceptable scalability and repeatability. There is also a need for a method of fabricating nanopores in a membrane material that reduces or avoids the use of highly toxic etchants such as HF. There is also a need for a method of fabricating nanopores in a membrane material that allows control over the size and shape of the nanopores. There is further a need for a method of fabricating nanopores in a membrane material that allows tuning of the nanopores according to the particular application of the membrane materials.

It is to be understood that, if any prior art is referred to herein, such reference does not constitute an admission that the prior art forms a part of the common general knowledge in the art, in Australia or any other country.

### SUMMARY

The present inventors have conducted research and development on the use of a track-etch process in the production of nanopores in materials. In an embodiment, the material may comprise or include inorganic materials, particularly silicon-based materials. In another embodiment, the material may comprise or include an organic material. In the track-etch process, membranes are irradiated to create long, narrow tracks of damage. These damaged regions are generally more susceptible to suitable chemical etchants than the bulk (undamaged) material. This difference in chemical etching rates between the track of damage and the undamaged material leads to the formation of nanopores.

In a first aspect there is disclosed a method of fabricating nanopores in a material, the method comprising:
irradiating the material to create a track of damage in the material, the
track of damage having one or more dimensions in the nanometre range; and
etching the track of damage with an etchant to produce a nanopore.

The irradiating step may comprise high energy irradiation.

In an embodiment, the irradiating step may comprise ion irradiation. The ion irradiation may comprise swift heavy ion irradiation. The ion irradiation causes the formation of tracks of damage along the ion trajectories in the material. These ion tracks are regions of damage that can be preferentially etched compared with undamaged material. The ion tracks may be about 3 to 15 nm in diameter and in the order of 10s to 100s of micrometres long.

The irradiation step determines the number of nanopores in the membrane as the number of ions hitting the membrane is translated into the number of nanopores. The heavy ions may be those ions that are heavier than Si. The heavy ions may have energies greater than 10 MeV.

The heavy ions may comprise Xe ions or Au ions. In one embodiment, the material was irradiated with 200 MeV Xe ions. In another embodiment the material was irradiated with 89 MeV Au ions. In another embodiment the material was irradiated with 185 MeV Au ions. In another embodiment the material was irradiated with 1.6 GeV Au ions.

In an alternative embodiment, the irradiating step may comprise laser irradiation. The laser irradiation causes the formation of a laser track in the material.

The irradiation step determines the number of nanopores created in the material. In the case of ion irradiation, the number of ions hitting the material is typically translated into the number of nanopores eventually created by subsequent etching. The density of nanopores can be varied from a single nanopore to ˜10¹⁰ nanopores per cm².

The material may comprise a membrane. The thickness of the membrane will depend on the intended function and application of the nanopore membrane. For instance, a thinner nanopore membrane (<100 nm) is more suitable for DNA and protein sensing applications while a thicker membrane is more suitable for filtration purposes, where the membrane is required to withstand the fluid pressure. In an embodiment, the membrane thickness is less than 50 nm, such as less than 30 nm. The membrane thickness may be as low as 1 nm, such as 1.5 nm or higher. Relatively thin membranes provide a greater signal-to-noise ratio (SNR), and larger capture radius compared to thicker membranes and are often perceived as a prerequisite for more captivating sequencing efforts. With nanopore technology being driven more towards sequencing—may it be genomic or proteomic—fabricating thin membranes has become more desirable for high-resolution measurements.

The membrane may have a thickness of up to 10 μm. The membrane may have a thickness of at least 10 nm.

In an embodiment, the membrane has a surface area of up to 25 mm². The minimum surface area may be at least 0.0001 mm².

The composition of the material may comprise one or more amorphous inorganic materials. Amorphous solids/materials are non-crystalline solids, i.e. the atoms/molecules in the solid are not organised in any definite pattern.

The composition of the material may be silicon based.

The composition of the material may comprise amorphous silicon.

The composition of the material may comprise one or more inorganic oxide materials.

The composition of the material may comprise one or more of the following:
silicon oxide,
silicon nitride,
silicon oxynitride,
hafnium oxide,
hafnium silicon oxide,
aluminium oxide,
titanium oxide,
zirconium oxide, and
tin oxide.

In an embodiment, the layer of membrane material may comprise diamond.

The present disclosure focusses on the formation of nanopores in silicon-based materials. Of particular interest are silicon oxides, silicon nitrides and silicon oxynitrides. Silicon dioxide, silicon nitride and silicon oxynitride are important inorganic materials known for their outstanding mechanical properties and use in Si microelectronics. Owing to their properties such as excellent mechanical and chemical resistance, high-temperature endurance, high density, negligible leakage currents, etc., the silicon dioxide and silicon oxynitride membranes are exceptional candidates to be used as chemical and/or biological sensors. Silicon oxynitrides have a wide use for optical sensors as well.

Where the membrane comprises a silicon nitride, it may comprise a near-stoichiometric SiₓN_{y} (x˜3 and y˜4).

Silicon oxynitride is an amorphous material whose composition varies between silicon dioxide and silicon nitride. It is an exciting material for many optical sensing applications as a large number of its properties can be varied by varying the oxygen and/or nitrogen content. By changing the ratio of oxygen to nitrogen content, the refractive index of the films can be easily tuned from 1.45 to 2.1. This property is highly usable for bio-optical sensors.

Where the material composition is silicon oxide, the material may comprise thermal oxides (ie, silicon oxide produced by thermal oxidation). Alternatively, the material may be formed by plasma-enhanced chemical vapor deposition (PECVD).

In some embodiment, the material is a monolithic material. In other embodiments, the material is a composite material. A composite material is a material formed by combining two or more materials with different physical and/or chemical properties. The resulting composite material exhibits physical and/or chemical characteristics different from those of the individual material components.

In some embodiments, the material may be a combination of different materials. By combining different materials, it is possible to make bipolar nanopores which may have better filtration performance. Also, such bipolar nanopores can be used as a nanofluidic diode to fabricate logic gates in solution phase and to mimic biological processes.

In some embodiments, the layer of membrane material is a single layer formed by a single material composition.

In some other embodiments, the layer of membrane material is multilayered. The layer of membrane material may comprise two or more sublayers having different compositions. The layers may comprise silicon, silicon oxide and/or silicon oxynitride. In some embodiments, the layer of membrane material is a combination of one or more amorphous inorganic materials and nanoparticles.

The resulting membranes have many applications in optical and opto-electronic devices and can be used to manipulate light-matter interactions.

In some embodiments, the layer of membrane material is a combination of one or more silicon based inorganic materials and nanoparticles.

In some embodiments, the layer of membrane material is a combination of one or more inorganic oxide materials and nanoparticles.

The nanoparticles may be inorganic nanoparticles.

The nanoparticles may be metal nanoparticles. In one embodiment, the nanoparticles are gold nanoparticles. In another embodiment, the nanoparticles are silver nanoparticles. In yet another embodiment, the nanoparticles are copper nanoparticles.

The nanoparticles may have a spherical shape and/or an elongated shape.

In some embodiments, the layer of membrane material comprises one type of metal nanoparticles. In other embodiments the layer of membrane material comprises two or more types of metal nanoparticles.

In some embodiments, the nanoparticles are dispersed in the layer of membrane material. In other embodiments, the nanoparticles are provided (such as by being embedded) between two layers of any one of the above-mentioned materials.

In some embodiments, the layer of membrane material comprises an inorganic oxide and gold nanoparticles. In another embodiment, the layer of membrane material comprises silicon oxide and gold nanoparticles. In another embodiment, the layer of membrane material comprises silicon nitride and gold nanoparticles.

In another embodiment, the layer of membrane material comprises silicon oxynitride and gold nanoparticles.

In an embodiment, the layer of membrane material comprises a doped layer between layers of one or more inorganic oxides. The layer of membrane material may comprise a layer of doped silicon as a sandwich layer between layers of one or more inorganic oxides. The inorganic oxides may comprise silicon oxide and/or silicon oxynitride. In some embodiments a layer of doped silicon is deposited between layers of silicon oxide and/or silicon oxynitride using sputtering deposition. In other embodiments, a layer of undoped silicon or any other semiconductor is deposited between layers of silicon oxide and/or silicon oxynitride using sputtering deposition and then doped to the required levels using ion-implanters or other methods.

In an embodiment, the membrane is in the form of a multilayered membrane. The layers may comprise silicon, silicon oxide and/or silicon oxynitride. In an embodiment, the layers comprise a layer of doped material between layers of one or more other materials. The layer of doped material may comprise a layer of doped semiconductor material. In an embodiment, the doped material comprises doped silicon as a sandwich layer between layers of one or more other materials. The one or more other materials may comprise silicon oxide and/or silicon oxynitride. Nanopores formed through such multilayered structures may form the basis for the fabrication of “gated nanopores”.

After the nanopore formation through such multilayered structures, a silicon oxide layer may be formed on the exposed silicon inside the nanopore. Rapid thermal annealing may be used to grow a thermal oxide layer on the exposed silicon inside the pore. Alternatively, a thin silicon oxide layer can be deposited on the pore surface using a deposition technique, such as atomic layer deposition, to avoid the electric currents through the gate.

Gated nanopore membranes may be used to mimic the biological channels inside cells. By controlling and gating the anionic or cationic flow through the membrane, the membranes may be used for applications such as sensing, therapeutics, neuromorphic computing, separation, and single-molecule detection. Also, inter-cation selectivity may be possible through the gated-nanopores; these gated nanopore structures can potentially be used to design artificial neurons. As noted above, the present method includes the step of etching the track of damage with an etchant to produce a nanopore.

In an embodiment, the etchant includes or comprises an aqueous hydroxide. In one embodiment, the etchant is an alkali hydroxide.

The etchant may comprise one or more of the following:
a. Potassium Hydroxide
b. Sodium hydroxide
c. Barium hydroxide
d. Lithium hydroxide
e. Calcium hydroxide
f. Ammonium hydroxide
g. Cesium hydroxide

In an embodiment, the etchant comprises one or more of potassium hydroxide or sodium hydroxide.

Alternatively, the etchant may be selected from hydrazine and xenon difluoride. However, such etchants be more corrosive than hydroxide etchants and therefore can present safety and environmental risks.

The concentration of the etchant may be at least 0.1 M. In an embodiment, the concentration may be a minimum of 0.2M. In an embodiment, the concentration may be a minimum of 0.5 M. In an embodiment, the concentration may be a minimum of 0.7M. In an embodiment, the concentration may be a minimum of 1 M. In an embodiment, the concentration may be a minimum of 1.5M. In an embodiment, the concentration may be a minimum of 2 M. In an embodiment, the concentration may be a minimum of 2.5M. In an embodiment, the concentration may be a minimum of 3 M. In an embodiment, the concentration may be a minimum of 3.5M. In an embodiment, the concentration may be a minimum of 4 M. In an embodiment, the concentration may be a minimum of 4.5M. In an embodiment, the concentration may be a minimum of 5 M. In an embodiment, the concentration may be a minimum of 5.5M. In an embodiment, the concentration may be a minimum of 6 M. In an embodiment, the concentration may be a minimum of 7 M. In an embodiment, the concentration may be a minimum of 8 M.

In an embodiment, the concentration may be a maximum of 15 M. In an embodiment, the concentration may be a maximum of 12 M. In an embodiment, the concentration may be a maximum of 10 M. In an embodiment, the concentration may be a maximum of 9 M. In an embodiment, the concentration may be a maximum of 8 M. In an embodiment, the concentration may be a maximum of 7 M. In an embodiment, the concentration may be a maximum of 6 M.

The etchant may further include hydrofluoric acid (HF). The HF may be used in combination with one or more of the listed etchants, either simultaneously or sequentially. The HF may be wet or vapour. If used, the HF may have a minimum concentration of 1 volume %, such as at least 1.5%. In an embodiment, the HF concentration may be at least 2%, such as at least 2.5%. The maximum HF concentration may be 5%.

The etching step may be conducted at an elevated temperature. By “elevated temperature” is meant a temperature above ambient temperature. The temperature of etching may be at least 30° C. In an embodiment, the temperature of etching may be at least 40° C. In an embodiment, the temperature of etching may be at least 50° C. In an embodiment, the temperature of etching may be at least 60° C. In an embodiment, the temperature of etching may be at least 70° C. In an embodiment, the temperature of etching may be at least 80° C. In an embodiment, the temperature of etching may be at least 90° C. In an embodiment, the temperature of etching may be a maximum of the boiling point of the etching solution, such as 100° C.

The temperature of etching can be adjusted in accordance to the etchant concentration and the desired size and shape of the fabricated nanopores as discussed in more detail below.

In a second aspect there is disclosed a process for tuning the geometry of nanopores formed by the method described above, said process including controlling one or more of the parameters: temperature, etchant composition, etchant concentration, material composition, density and morphology during the etching step to thereby control the geometry of the nanopores. As used herein the term “geometry” of the nanopore refers to the overall shape and size of the nanopore. The geometry includes such parameters as cone angle, radius and symmetry of the nanopore. The symmetry includes whether the nanopore is a combination of different shapes, such as a cone and a cylinder, or two cones having different cone angles.

As used herein, “cone angle” or “cone opening angle” is the angle made by the side walls of a nanopore along a cross-section through the apex and centre of its base. “Half cone angle” is half of the cone angle, i.e. the angle between the cone's axis and a side wall of the nanopore. Conical-shaped nanopores enable an enhanced rate of transport through the membrane and a higher sensitivity in bio- and chemical-sensing applications relative to an analogous cylindrical pore membrane. Moreover, with appropriate dimensions, conical and hour-glass (double conical) nanopores can exhibit nanofiltration and ion current rectification properties. Such nanopores enables charge selective ion transport through the pores. They can also reject different ions depending upon if the solution enters from the tip or from the base of the nanopore.

As used herein “radius” means the maximum radius of the nanopore. Where the nanopore is or includes a conical (or frustoconical) shape, the radius means the base radius of the cone. If the nanopore has a cone or truncated cone shape, there are two radii, the maximum (or base) radius and the minimum (or tip) radius. However, unless otherwise stated, “radius” in the present disclosure is intended to refer to the maximum (or base) radius of the conical or truncated conical nanopore.

Additionally, the size of the nanopore as well as the cone angle influences the sensing performance of the nanopores. With larger cone angles, the effective pore length decreases (giving higher throughput), and the capture radius (radius under which the biomolecules can be detected) increases, making these nanopores very suitable for molecular sensing, protein detection, and DNA sequencing. It has been shown earlier using numerical simulations that by varying the cone angle and the nanopore height, properties such as ion current rectification properties, resistive pulse sensing, etc. can be varied. Therefore, tuning the nanopore cone angles allows the fabrication of nanopores that are adapted for the requirements of a specific application.

As used herein, the term “tuning” means the ability to change one or more parameters of the nanopore. In other words, tuning can be understood as adjusting the nanopore shape and/or structure and/or size for a specific application. In an embodiment, the step of tuning the geometry of the nanopores includes tuning one or more of cone angle, radius and symmetry of the nanopores.

For a given material composition, etchant composition, etchant concentration and etching time, with increasing temperature of etching:
the cone angle of the nanopore decreases; and/or
the radius of the nanopore increases.

For a given material composition, etchant composition, temperature and time of etching, with increasing concentration of etchant:
the cone angle of the nanopore increases; and/or
the radius of the nanopore increases.

The composition of the material may also be varied. For example, the stoichiometry and density of PECVD grown silicon dioxide membranes may be varied to tune the nanopore dimensions. Further, where the membrane comprises silicon oxynitride, by changing the ratio of oxygen to nitrogen content, the refractive index of the films can be tuned from 1.45 to 2.1, which again influences the geometry of nanopores formed therein.

The above relationships may be used to tune the geometry of the nanopores. In one example, where it is desired to have a relatively low cone angle of the nanopores, the etching step may be conducted at a relatively high temperature and/or a relatively low etchant concentration. In another example, where it is desired to have a relatively high nanopore radius, the etching step may be conducted at a relatively high temperature of etching and/or a relatively high etchant concentration.

The cone angles of the nanopores can be tuned to be from approximately 3 degrees to 110 degrees. In an embodiment, cone angles of the nanopores can be tuned to be from approximately 10 degrees to 110 degrees. Accordingly, the half cone angles may be tuned from approximately 1.5 degrees to 55 degrees, for example from 5 degrees to 55 degrees. In an embodiment, the half cone angle may be tuned from approximately 25 degrees to approximately 55 degrees.

The radius and depth of the nanopores can also be tuned according to the need of the application. Both radius and depth of the nanopores can be varied from approximately 20 nm to the order of a few microns. In some embodiment, the depth of the nanopores is up to 10 μm.

The overall geometry of the nanopore can be tuned to provide complex nanopore shapes by using a combination of etchants. For example, an overall funnel shaped nanopore can be produced by etching using a combination of wet HF and vapour HF. Using wet HF etching, the conical part of the funnel-shaped nanopore is fabricated and using vapour HF etching, the cylindrical part of the nanopore is fabricated. It is to be noted that the conical part of the nanopore can alternatively be fabricated using alkali hydroxide etchant and the cylindrical part fabricated using vapour HF.

The following discusses some examples of uses for nanopores having different geometries.

Single conical nanopores are, for example used for electrically driven salt flux rectification, which has applications in the field of nanofiltration, energy generation, ion-pumps etc. Due to inherent rectification properties, conical nanopores have many advantages over cylindrical nanopores. For instance, hindered diffusion occurs throughout the entire length of the nanopore in a cylindrical nanopore, while it occurs only at the tip of a conical nanopore. As a consequence, conical nanopore membranes exhibit higher flux/flow and yield better and faster separation of proteins, biomolecules etc. over cylindrical nanopores. These advantageous properties of conical nanopores are influenced by the size of the cone angles, exhibiting an increased effect with increase in cone angles. Therefore, tuning the nanopore cone angles and fabricating nanopores with large cone angles as disclosed herein allows the fabrication of nanopores with great potential in all the above-mentioned applications.

Double conical symmetric nanopores are particularly suitable for filtration applications. The driving force required to operate the separation is lower as compared to the single conical nanopore of same length. Additionally, the double conical nanopores can also act as logic gates, nanofluidic diode by functionalizing one part of the nanopore or by fabricating nanopore out of two different oxides.

Funnel shaped nanopores are bio-inspired (eg, similar shaped nanopores are found in the human body for chloride transport) and have a high rectification ratio, which leads to higher asymmetric ion transport. These nanopores have also enhanced optical transmission efficiency. Funnel shaped nanopores are particularly suitable for applications in the fields of materials, electronics, and life sciences.

Asymmetric double conical nanopores are particularly suitable for asymmetric ion transport. Due to their different cone angles and/or shapes, these nanopores can be used for asymmetric ion transport even without any external driving force. Even with driving forces such as an electrical force, these nanopores will allow the flow of one kind of ions from one side of the solution and other kind of ions from other side of solution.

In addition to the exemplary applications discussed above, all the above mentioned nanopores can be used as templates to synthesise different shaped nanowires.

Accordingly, the method disclosed herein enables the production of nanopore membranes that may have one or more of the following advantages:
The ability to avoid or at least reduce the use of toxic and dangerous etchants, such as HF. Furthermore, using HF as an etchant alone, greatly limits the geometry of the nanopores. For example, it is not possible to fabricate conical (or truncated conical) or funnel shaped pores and vary the opening angles (also referred to as cone angle) of the conical/funnel shaped nanopores using HF alone as the etchant.
The use of less toxic etchants, the composition and/or concentration thereof may be varied to tune the geometry of nanopores.
High tunability of the nanopores by varying material composition, temperature of etching, etchant composition and concentration.
High scalability. The ion irradiation process is highly scalable. The irradiation area can easily be varied from few microns to few meters. Further, the number of nanopores can be varied from a single nanopore to 10¹⁰ nanopores per cm². The etching process is highly scalable as well. Thousands of membranes can be etched together at once.
The process is compatible with complementary metal-oxide-semiconductor (CMOS) production processes. It is therefore an industrially viable process for integration in different devices.
The process is highly reliable with a high repeatability rate.
Many potential applications that may include chemical and biological sensing, size and charge selective ion transport, water desalination, ion pumps, DNA sequencing, molecular sieving, water filtration, protein separation and detection and health monitoring.

### BRIEF DESCRIPTION OF THE DRAWINGS

Embodiments will now be described by way of example only, with reference to the accompanying drawings in which:

FIGS. 1 (a) and (b) are schematic diagrams showing embodiments of the fabrication process disclosed herein. FIG. 1(a) shows fabrication of tunable nanopores using KOH, NaOH and their combination as etchant. FIG. 1 (b) shows the fabrication process of real-funnel shaped nanopores using a combination of wet and vapour HF etching.

FIGS. 2 (a) to (d) show SEM images of embodiments of the membrane disclosed herein: (a) SEM image showing a large number of nanopores in a thin silicon dioxide membrane. (b) Top-view SEM image showing single-sided conical nanopores fabricated in a silicon oxynitride membrane. (c) Cross-section SEM image showing single-sided etched conical nanopores in silicon dioxide membrane. (d) Cross-sectional SEM image showing a double-sided etched conical nanopore in a silicon dioxide membrane.

FIGS. 3 (a) and (b) are graphs showing: (a) nanopore radius as a function of etching time at temperatures of 70° C. (squares), 80° C. (circles), and 90° C. (triangles); and (b) the half cone angle of the nanopores as a function of etching temperature.

FIG. 4 is an Arrhenius plot of the radial etch rates in Example 1. The dotted line indicates the linear fit to the data, which gives the activation energy for etching.

FIGS. 5 (a) and (b) are graphs showing: (a) nanopore radius as a function of etching time. The etching temperature was kept constant at 80° C. The etchant concentrations were 1M (squares), 3 M (circles), 6 M (triangles) and 9 M (inverted triangles). The linear fits to the data give the etching rate, which is plotted as a function of etchant concentration (b).

FIG. 6 is a graph of half cone angles of the nanopores as a function of the concentration of the etchant in Example 2.

FIG. 7: is a plot showing the nanopore radius as a function of the refractive index of different silicon oxynitride films in Example 4.

FIGS. 8 (a) and (b) are a top view (a) and cross-section (b) SEM image of funnel shape nanopores.

FIG. 9 is a schematic drawing showing the fabrication process of symmetric and asymmetric double conical gated nanopores.

### DETAILED DESCRIPTION

In the following detailed description, reference is made to accompanying drawings which form a part of the detailed description. The illustrative embodiments described in the detailed description, depicted in the drawings and defined in the claims, are not intended to be limiting. Other embodiments may be utilised, and other changes may be made without departing from the spirit or scope of the subject matter presented. It will be readily understood that the aspects of the present disclosure, as generally described herein and illustrated in the drawings can be arranged, substituted, combined, separated and designed in a wide variety of different configurations, all of which are contemplated in this disclosure.

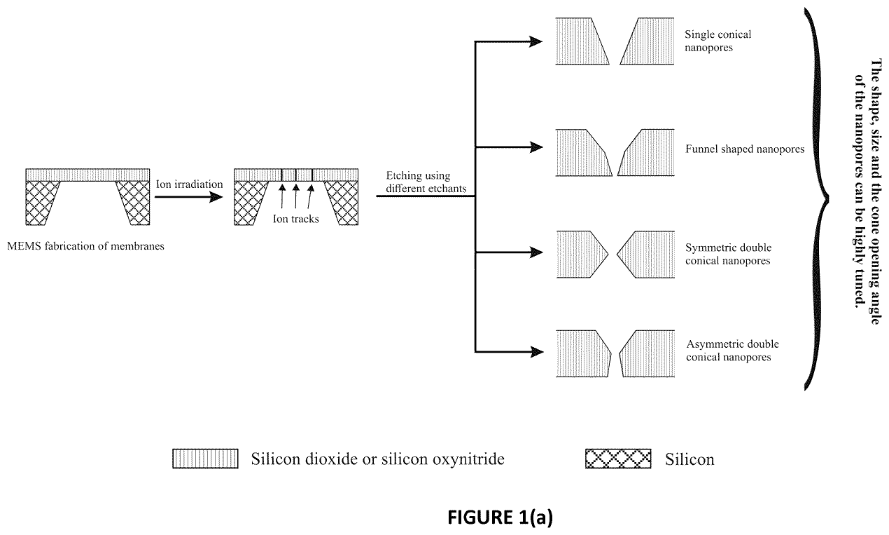

Referring firstly to FIG. 1, a schematic diagram shows the fabrication process of tunable nanopores using KOH, NaOH and their combination as etchants. FIG. 1 (a) illustrates the process and shows different nanopore shapes that can be fabricated using the present method. The membranes comprise silicon dioxide or silicon oxynitride and are each supported on a silicon frame. The membranes are irradiated with swift heavy ions to form ion tracks in each membrane. Each membrane is then etched using a different etchant and/or under different etching conditions. There is a variety of nanopore geometries produced according to the particular etchant or etching conditions, including single conical, funnel shaped symmetric double conical and asymmetric double conical.

FIG. 1 (b) illustrates the steps for producing funnel shaped nanopores in these membranes using the combination of wet and vapour HF etching. Using wet HF etching, the conical part of the funnel-shaped nanopore is fabricated and using vapour HF etching, the cylindrical part of the nanopore is fabricated. It is to be noted that the conical part of the nanopore can alternatively be fabricated using alkali hydroxides and the cylindrical part fabricated using vapour HF.

FIGS. 1(a) and (b) illustrate the fabrication of a variety of nanopore geometries, such as single conical, double conical, funnel-shaped, symmetric, and asymmetric nanopores. Each different nanopore shape may have a different application. Single conical nanopores are, for example used for electrically driven salt flux rectification, which has applications in the field of nanofiltration, energy generation, ion-pumps etc. Due to inherent rectification properties, conical nanopores have many advantages over cylindrical nanopores. For instance, hindered diffusion occurs throughout the entire length of the nanopore in a cylindrical nanopore, while it occurs only at the tip of a conical nanopore. As a consequence, conical nanopore membranes exhibit higher flux/flow and yield better and faster separation of proteins, biomolecules etc. over cylindrical nanopores. These advantageous properties of conical nanopores are influenced by the size of the cone angles, exhibiting an increased effect with increase in cone angles. Therefore, tuning the nanopore cone angles and fabricating nanopores with large cone angles as disclosed herein allows the fabrication of nanopores with great potential in all the above-mentioned applications.

Double conical symmetric nanopore are particularly suitable for filtration applications. The driving force required to operate the separation is lower as compared to the single conical nanopore of same length. Additionally, the double conical nanopores can also act as logic gates, nanofluidic diode by functionalizing one part of the nanopore or by fabricating nanopore out of two different oxides. Funnel shaped nanopores are bio-inspired (similar shaped nanopores are found in the human body for chloride transport) and have a high rectification ratio, which leads to higher asymmetric ion transport. These nanopores have also enhanced optical transmission efficiency. Funnel shaped nanopores are particularly suitable for applications in the fields of materials, electronics, and life sciences.

Asymmetric double conical nanopore are particularly suitable for asymmetric ion transport. Due to their different cone angles and/or shapes, these nanopores can be used for asymmetric ion transport even without any external driving force. Even with driving forces such as an electrical force, these nanopores will allow the flow of one kind of ions from one side of the solution and other kind of ions from the other side of solution.

In addition to the exemplary applications discussed above, all the above mentioned nanopores can be used as templates to synthesise different shaped nanowires.

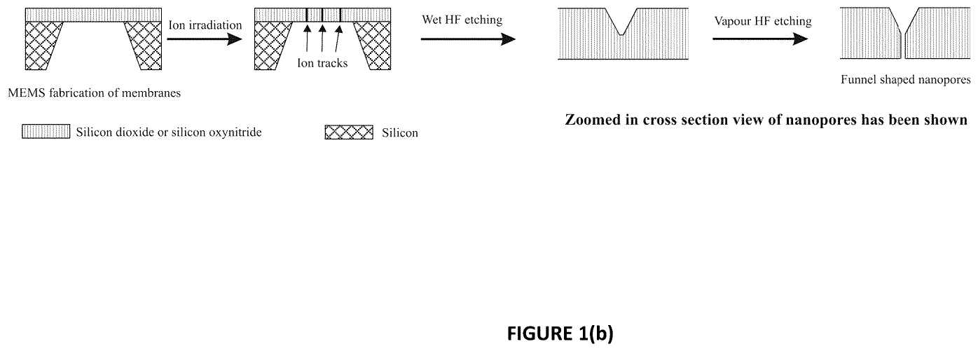

FIG. 2 shows scanning electron microscopy (SEM) images for a number of different samples of membranes produced according to the disclosed method. FIG. 2 (a) shows a side view of a large number of pores in a thin silicon dioxide membrane, with the length of the scale bar being 1 micron. FIG. 2 (b) shows the top view SEM image of single-sided conical etched nanopores in silicon oxynitride, with the length of the scale bar being 4 microns. FIG. 2 (c) and (d) show cross-section SEM images of single and double conical pores in silicon dioxide membrane respectively, with the length of the scale bars both being 200 nm.

### EXAMPLES

Non-limiting Examples of the method of fabricating nanopores in a material will now be described.

### Examples 1 to 3

Samples of silicon dioxide membranes with a surface area of 300 μm×300 μm and a thickness of 1 μm were used for the fabrication of nanopores. The membranes comprised thermal oxides (ie, silicon oxide produced by thermal oxidation) as well as membranes produced using plasma-enhanced chemical vapor deposition (PECVD).

Some samples were irradiated at the isochronous cyclotron U-150M at the Institute of Nuclear Physics, Kazakhstan, with 200 MeV Xe ions, some at the UNILAC linear accelerator at the GSI Helmholtz Centre for Heavy Ion Research, Germany with 1.6 GeV Au ions and some at the 14UD accelerator, at the Australian National University, Australia with 185 MeV and 89 MeV Au ions. The irradiation with the swift heavy ions formed long, narrow tracks of damage along the ion trajectories. These damaged regions, called ‘ion-tracks’, are about 3 to 15 nm in diameter and 10s to 100s of micrometres long and are generally more susceptible to suitable chemical etchants than the bulk (undamaged) material. This chemical etching of the ion-track leads to the formation of nanopores. The samples were then etched using different etchants, at different concentrations and different temperatures. The influence of these parameters is explained in the following Examples.

### Example 1: Effect of Temperature

The thermal silicon dioxide membranes were irradiated with 1.6 GeV Au ions with a fluence of 108 ions per cm². The damaged regions (ion tracks) in the membranes were etched using 6M KOH as an etchant to convert the ion tracks into nanopores. The etchant concentration was kept constant, and the samples were etched at different temperatures to study the influence of the temperature on the etching kinetics of the nanopore membranes. The etched samples were then observed in SEM to measure the radius and half cone angle of the nanopores (through cross-section SEM imaging).

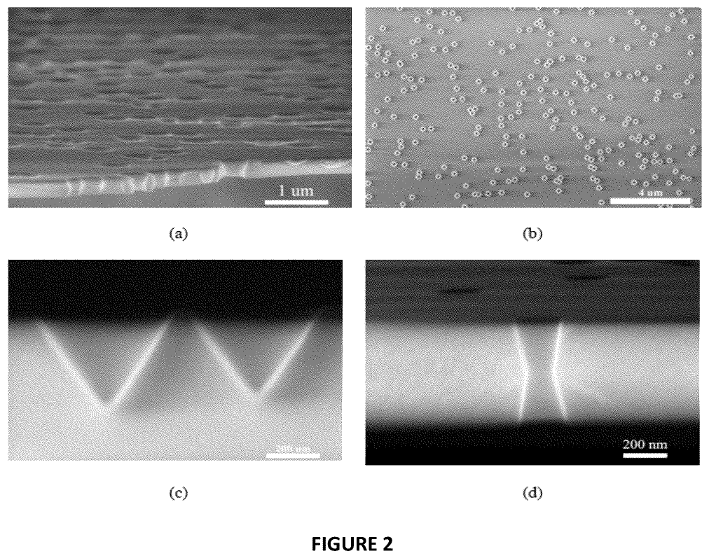

FIG. 3(a) shows the radius of the nanopores observed from SEM as a function of etching time. The samples were etched at three different temperatures, 70° C., 80° C., and 90° C., while keeping the etching concentration the same. The linear fits to the data give the radial etching rate of the nanopore membranes. It was found that the radial etch rate increases with increasing temperature.

The half cone angle values as a function of etching temperature are plotted in FIG. 3 (b). As is evident from the figure, the half cone angle values reduce with increasing temperature, which directly indicates that the axial etch rate increases quicker than the radial etch rate with increasing temperature.

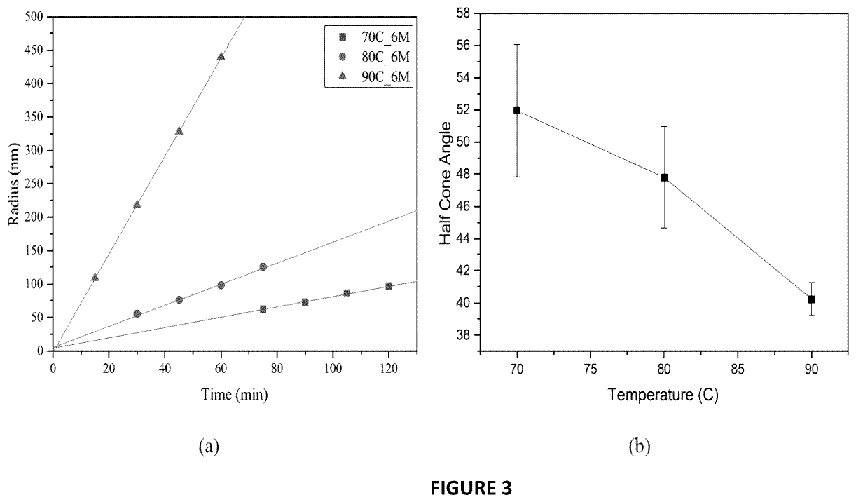

Measurements show that the increase in the radial etch rate with temperature can be described by Arrhenius law, as shown in FIG. 4. The activation energy of Eₐ=(1.25±0.14) eV using 6M KOH was deduced from the plot.

These results illustrate that the activation energy for the track etch rate and radial etch rate is different which results in different cone angles at different temperatures. These results show that just by changing the processing temperature, the cone angle of the fabricated nanopores can be adjusted accordingly. Thus, changing the process temperature enables a high level of tunability of the shape of the nanopores.

### Example 2: Effect of the Etchant Concentration

Nanopores were fabricated using four different etchant concentrations. The etchants used were 1M, 3M, 6M, and 9M KOH solutions. The silicon dioxide membranes were etched while keeping the etching temperature at a constant value of(80±1) ° C.

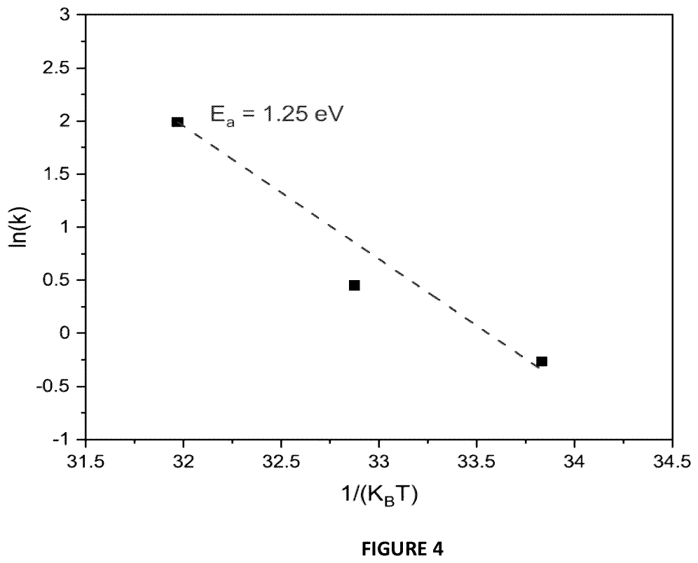

The radius of the nanopores as a function of time is shown in FIG. 5 (a). The linear fits to the data gave the etching rates, which are plotted as a function of etchant concentration in FIG. 5 (b). The etching rate increased from (0.99±0.03) nm/min for 1M KOH to (1.97±0.06) nm/min for the case of 3M KOH. The etching rate then reduced to a value of (1.57±0.03) nm/min for the case of 6M KOH, before increasing to a value of (3.77±0.11) nm/min for 9M KOH.

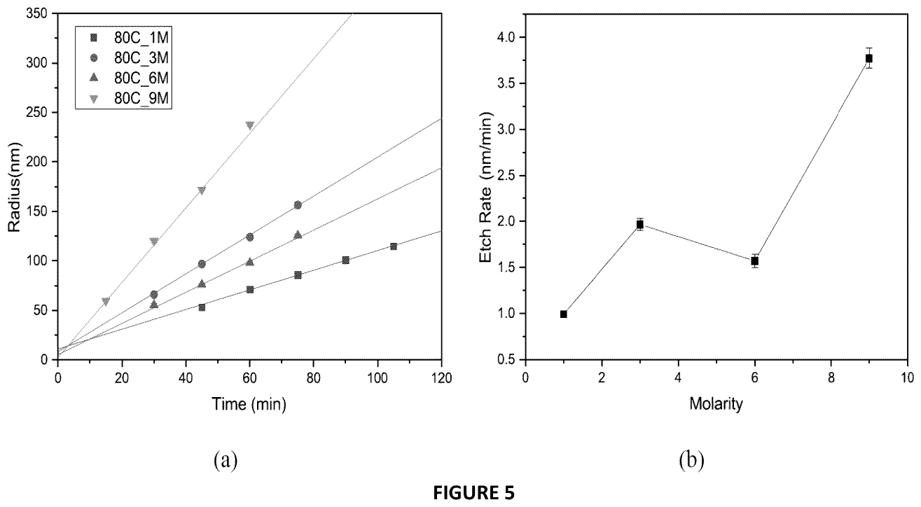

FIG. 6 shows the half cone angles as a function of etching concentration. As is evident, the half cone angle values increase with increasing concentration of the etchant. Thus, varying the concentration of the etchant provides another avenue of tuning the nanopore shape and size. This is very important as by combining the effect of both temperature and concentration of the etchant, it is possible to fine tune the cone-angle, increase/decrease the etching rate and tune the size of the cones as well.

### Example 3: Effect of the Method of Making the Membrane Composition

As noted above, both thermal oxide and the PECVD grown oxide were used for the fabrication of the nanopore membranes. Whereas thermally grown oxide is of higher quality (less defects, less hydrogen content, denser, better dielectric properties etc.), PECVD deposition allows control over the membranes' properties, including stoichiometry, density, refractive index, and the resultant stress. It is also possible to integrate PECVD oxide in multilayer structures.

The PECVD films were deposited at a temperature of 650° C.

It was found that there was a difference between the nanopores in thermal oxide as compared to PECVD silicon oxide membranes. The half cone angle was found to be more than double in the case of PECVD silicon oxide membranes when etched using 3M KOH at 80° C. Also, the etching rate was higher in the case of PECVD films. These results give the possibility to manoeuvre these observations even more and further tune the shape and size of the nanopores. Accordingly, the material composition, purity and/or microstructural properties can be manipulated and controlled to further tune the geometry of the nanopores.

### Example 4: Formation of Nanopores in Silicon Oxynitride

Silicon oxynitride is an amorphous material whose composition varies between silicon dioxide and silicon nitride. It is an exciting material for many optical sensing applications as a large number of its properties can be varied by varying the oxygen and/or nitrogen content. By changing the ratio of oxygen to nitrogen content, the refractive index of the films can be easily tuned from 1.45 to 2.1. This property is highly usable for bio-optical sensors. A number of silicon oxynitride membranes of different refractive index and composition were fabricated using PECVD, as shown in Table 1. The refractive index of the membranes was found by fitting the ellipsometry reflective data to a Tauc-Lorentz Model.

TABLE 1
Gas flux and processing temperature for plasma-enhanced chemical
vapor deposition of different silicon oxynitride membranes.

| Sample | Refractive | N₂O | NH₃ | N₂ | SiH₄ | Temperature |
|---|---|---|---|---|---|---|
| Number | Index | (sccm) | (sccm) | (sccm) | (sccm) | (° C.) |
| 1 | 1.49 | 710 | 0 | 270 | 14 | 650 |
| 2 | 1.51 | 580 | 2.8 | 400 | 14 | 650 |
| 3 | 1.53 | 455 | 5.6 | 525 | 14 | 650 |
| 4 | 1.55 | 325 | 8.4 | 655 | 14 | 650 |
| 5 | 1.61 | 190 | 10.5 | 790 | 14 | 650 |
| 6 | 1.64 | 130 | 11.5 | 850 | 14 | 650 |
| 7 | 1.73 | 60 | 12.5 | 900 | 14 | 650 |

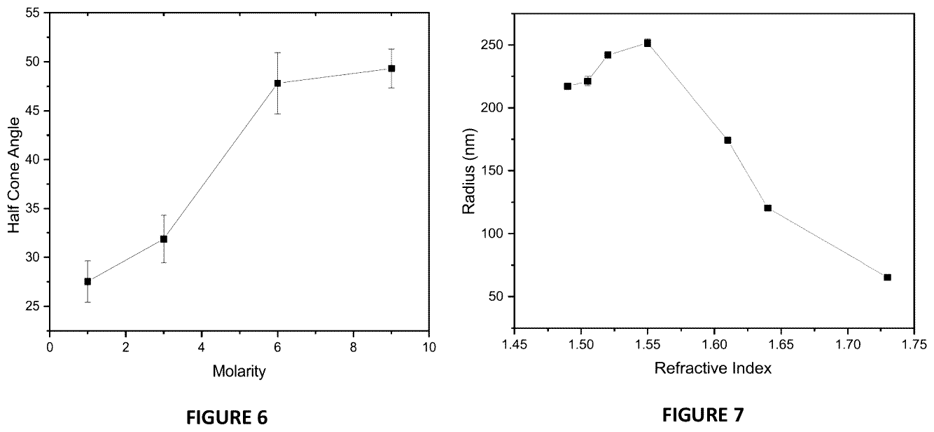

The samples were irradiated at the isochronous cyclotron U-150M at the Institute of Nuclear Physics, Kazakhstan, with 200 MeV Xe ions. The different silicon oxynitride membranes were then etched at 90° C. using 3M KOH as an etchant for 90 mins. The nanopore radius as a function of the refractive index is shown in FIG. 7. The etching rate first increases with the increasing nitrogen content and decreases afterwards. Also, the cone angles vary with the change in the composition of the membranes. The cone angle values decrease with an increase in the nitrogen content of the films. This also allows us to tune the pore structure further. Using these results and properties of the membranes, one could have integrated optical waveguide in multilayered systems and also do optical trapping of biomolecules.

### Example 5: Fabrication of Nanopores Using a Combination of Etchants

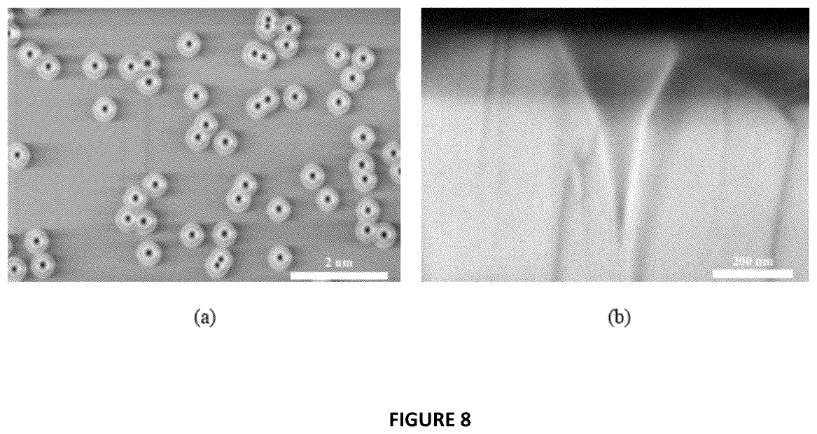

KOH and NaOH were used as the etchants for etching the ion-tracks. The influence of etching concentration, and temperature was previously discussed for the case of KOH. Similar results have been observed for the case of etching with NaOH as well. For instance, an etch rate of (4.87±0.14) nm/min and a half cone angle of (32.84±1.93) degrees were observed for thermal silica samples etched at 90° C. using 3M NaOH. The results presented show that using a combination of different etchants, etchants of different concentrations and etchants at different temperatures, nanopores of different shapes and sizes can be fabricated. These include near funnel-shaped pores, and asymmetric double conical nanopores. FIG. 8 shows an example of such a case; (a) shows the top view SEM image and (b) shows the cross-section SEM image of near funnel-shaped nanopores. These nanopores were fabricated by first etching the thermal oxide membranes using 3M KOH at 90° C. for 45 mins and then using 2.5% HF at room temperature for 10 mins.

Similarly, a combination of different etchants may be utilised to fabricate and fine-tune the nanopore shape and size for the application's requirement. As explained previously, fabrication of real funnel shaped nanopores can be achieved using a combination of wet alkali and vapour HF etching and/or wet and vapor HF etching. Both near-funnel shaped nanopores fabricated by combination of KOH and HF and actual funnel shaped nanopores fabricated by combination of wet and vapour HF etching have better current rectification properties as well as better ion selectivity as compared to conical nanopores. The current rectification factor can be increased by more than 100% by varying the cylindrical section of funnel shaped nanopores.

### Example 6: Manufacture of Gated Nanopores

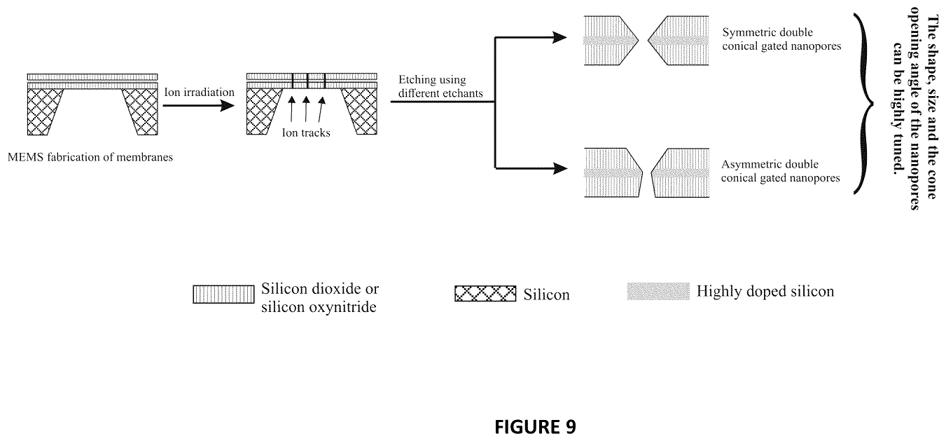

A multilayered membrane was formed that comprised a highly doped silicon as a sandwich layer in between silicon oxide and/or silicon oxynitride layers. The thickness of the layers of silicon oxide and/or silicon oxynitride on both sides of the doped silicon layer can be adjusted. As shown in FIG. 9, the nanopores were formed by ion irradiation to form ion tracks through the multilayered membrane, followed by etching of the ion tracks to form the nanopores. KOH or NaOH were used to etch the gated nanopores. These etchants can fabricate these nanopore structures, as they etch damaged regions both in silicon dioxide/silicon oxynitride layers as well as the middle silicon layer. FIG. 9 shows the formation of both symmetric and asymmetric double conical nanopores. After the nanopore formation, rapid thermal annealing was used to grow a thermal oxide layer on the exposed silicon inside the pore. The thermal oxide layer acts as an insulating layer that protects the leakage of current from the doped silicon into the solution/electrolyte while conducting experiments (for e.g., sensing, ion-rejection, molecular sieving etc.). Alternatively, a thin silicon oxide layer can be deposited on the pore surface using a deposition technique, such as atomic layer deposition, to avoid the electric currents through the gate.

Whilst a number of specific method and device embodiments have been described, it should be appreciated that the method and device may be embodied in many other forms.

In the claims which follow, and in the preceding description, except where the context requires otherwise due to express language or necessary implication, the word “comprise” and variations such as “comprises” or “comprising” are used in an inclusive sense, i.e. to specify the presence of the stated features but not to preclude the presence or addition of further features in various embodiments of the apparatus and method as disclosed herein.

Further patent applications may be filed in Australia or overseas on the basis of, or claiming priority from, the present application. It is to be understood that the following claims are provided by use of example only and are not intended to limit the scope of what may be claimed in any such future applications. Features may be added to or omitted from the claims at a later date so as to further define or re-define the invention or inventions.

1. A method of fabricating nanopores in a-material, the method comprising: irradiating the material to create a track of damage in the material, the track of damage having one or more dimensions in the nanometre range; and etching the track of damage with an etchant to produce a nanopore.

2. The method of claim 1, wherein the irradiating step comprises ion irradiation.

3. The method of claim 1, wherein the irradiating step comprises ion irradiation, preferably swift heavy ion irradiation and the track of damage comprises an ion track.

4. The method of any one of the precedent claims, wherein the material is a membrane.

5. The method of claim 4, wherein the membrane has a thickness of up to 10 μm.

6. The method of claim 4 or claim 5, wherein the membrane has a thickness of at least 10 nm.

7. The method of any one of claims 4 to 6, wherein the membrane has an area of up to 25 mm².

8. The method of any one of claims 4 to 7, wherein the membrane has an area of at least 0.0001 mm².

9. The method of any one of the preceding claims, wherein the composition of the material comprises one or more amorphous inorganic materials.

10. The method of any one of the preceding claims, wherein the composition of the material is silicon based.

11. The method of any one of the preceding claims, wherein the composition of the material comprises amorphous silicon.

12. The method of any one of claims 1 to 10, wherein the composition of material comprises one or more inorganic oxide materials.

13. The method of any one of claims 1 to 9, wherein the composition of the material comprises one or more of the following
silicon oxide,
silicon nitride,
silicon oxynitride,
hafnium oxide,
hafnium silicon oxide,
aluminium oxide,
titanium oxide,
zirconium oxide, and
tin oxide.

14. The method of any one of the preceding claims, wherein the etchant includes or comprises an aqueous alkali hydroxide.

15. The method of claim 14, wherein the etchant is selected from:
a. Potassium Hydroxide
b. Sodium hydroxide
c. Barium hydroxide
d. Lithium hydroxide
e. Calcium hydroxide
f. Ammonium hydroxide
g. Cesium hydroxide

16. The method of any one of claims 1 to 14, wherein the etchant is selected from hydrazine and xenon difluoride.

17. The method of any one of the preceding claims, wherein the etchant further includes HF.

18. A process for tuning the geometry of nanopores formed by the method of any one of claims 1 to 17, said process including controlling one or more of the following parameters:
(i) material composition and material refractive index and/or
(ii) temperature, etchant composition and etchant concentration during the etching step
to thereby control the geometry of the nanopores.

19. The process of claim 18, wherein the geometry of the nanopores includes one or more of cone angle, radius and symmetry.

20. The process of claim 19, wherein the cone angle of the nanopore is selectively decreased by increasing the temperature of etching.

21. The process of claim 19, wherein the cone angle of the nanopore is selectively increased by increasing the concentration of etchant.

22. The process of claim 19, wherein the radius of the nanopore is selectively increased by increasing the temperature of etching.

23. The process of claim 19, wherein the radius of the nanopore is selectively increased by increasing etchant concentration during etching.

24. A membrane including one or more nanopores fabricated using the method of any one of claims 1 to 17.

25. A membrane including one or more nanopores tuned using the process of any one of claims 18 to 23.

26. A membrane having one or more nanopores, wherein the composition of the membrane comprises one or more of the following materials:
amorphous silicon,
silicon oxide,
silicon nitride,
silicon oxynitride,
hafnium oxide,
hafnium silicon oxide,
aluminium oxide,
titanium oxide,
zirconium oxide, and
tin oxide,
wherein the geometry of the one or more nanopores is conical based.

27. The membrane of any one of claims 24 to 26, wherein the density of nanopores is between 1 and approximately 10¹⁰ nanopores per cm².

28. The membrane of any one of claims 24 to 27, wherein the geometry of the one or more nanopores is single-conical, funnel-shaped, symmetric double-conical or asymmetric double-conical.

29. The membrane of any one of claims 24 to 28, wherein the membrane has thickness of 20 nm to 10000 nm.

30. The membrane of any one of claims 24 to 29, wherein the membrane has a surface area of 0.0001 mm² to 25 mm².

31. The method of claim 4, wherein the membrane is multilayered.

32. The method of claim 31, wherein the membrane comprises a semiconductor, such as a doped silicon, as a sandwich layer in between silicon oxide and/or silicon oxynitride layers.

33. The method of claim 32, wherein the nanopores are gated nanopores.
